(19) United States
(12) Patent Application Publication
(10) Pub. No.: US 2026/0271284 A1
(43) Pub. Date: Sep. 10, 2026

(54) MANUFACTURING METHOD FOR MEMORY DEVICE, AND MEMORY DEVICE

(71) Applicant: WUHAN XINXIN SEMICONDUCTOR MANUFACTURING CO., LTD., Wuhan (CN)

(72) Inventors: FENGCONG GONG, WUHAN (CN); KAIWEI CAO, WUHAN (CN)

(21) Appl. No.: 19/663,234

(22) Filed: Apr. 29, 2026

Related U.S. Application Data
(63) Continuation of application No. PCT/CN2023/135174, filed on Nov. 29, 2023.

(30) Foreign Application Priority Data
Nov. 1, 2023 (CN) 202311456945.X

(51) Int. Cl. H10B 41/30

(52) U.S. Cl. CPC H10B 41/30

(57) ABSTRACT

A manufacturing method for a memory device, and a memory storage device. The manufacturing method includes: providing a semiconductor substrate, where the semiconductor substrate includes a substrate and gate structures, some gate structures are disposed within a memory region, a source and a drain are arranged on opposite sides of each gate structure in a first direction, and the memory region includes a source lead-out region; and covering a first interlayer dielectric layer on the semiconductor substrate, and forming source contact window structures within the first interlayer dielectric layer. Each source contact window structure extends along a second direction and is connected to sources in a same row along the second direction; each source contact window structure in the source lead-out region includes a source connection structure and a source contact structure. A cross-sectional area of the source contact structure is larger than that of the source connection structure.

### CROSS-REFERENCE TO RELATED APPLICATIONS

The present application is a continuation-application of International (PCT) Patent Application No. PCT/CN2023/135174, filed on Nov. 29, 2023, which claims priority of Chinese Patent Application No. 202311456945.X, filed on Nov. 1, 2023, in the National Intellectual Property Administration of China, the entire contents of which are hereby incorporated by reference in its entirety.

### TECHNICAL FIELD

The present disclosure relates to the field of semiconductor technologies, and in particular to a manufacturing method for a memory device and a memory device.

### BACKGROUND

During the application of integrated circuits, the performance of various devices is influenced by the spacing between different material layers. This effect is particularly pronounced in memory devices, where the interlayer spacing directly impacts the metal interconnections of the devices.

In practical operations, the R&D personnel involved in the present disclosure observed that in current semiconductor device manufacturing solutions, particularly in the fabrication of memory devices, the back-end process for forming gate structures requires high precision in metal routing. If alignment between vias and contacts is necessary, the process margin for the contact between vias and contacts becomes smaller. This reduction, due to overlay issues, decreases the contact area between vias and contacts, thereby increasing the corresponding contact resistance and affecting the performance of the semiconductor devices.

### SUMMARY OF THE DISCLOSURE

The present disclosure provides a manufacturing method for a memory device and a memory device.

A manufacturing method for a memory device, including:
providing a semiconductor substrate; wherein the semiconductor substrate includes a substrate and a plurality of gate structures; some of the plurality of gate structures are disposed within a memory region; a source is arranged on a side of each gate structure in a first direction, and a drain is arranged on an opposite side of the gate structure in the first direction; the memory region includes a source lead-out region; and
forming a first interlayer dielectric layer on the semiconductor substrate, and forming a plurality of source contact window structures within the first interlayer dielectric layer; wherein each source contact window structure extends along a second direction and is connected to a plurality of the sources in a same row along the second direction; each source contact window structure in the source lead-out region includes a source connection structure and a source contact structure that are stacked sequentially, wherein a cross-sectional area of the source contact structure is larger than a cross-sectional area of the source connection structure.

A memory device, including:
a substrate;
a plurality of gate structures; wherein some of the plurality of gate structures are disposed within a memory region; a source is arranged on a side of each gate structure in a first direction, and a drain is arranged on an opposite side of the gate structure in the first direction; the memory region includes a source lead-out region;
a first interlayer dielectric layer, covering the substrate, the plurality of gate structures, the drain, and the source; and
a plurality of source contact window structures, located within the first interlayer dielectric layer; wherein each source contact window structure extends along a second direction and is connected to a plurality of the sources in a same row along the second direction; each source contact window structure in the source lead-out region includes a source connection structure and a source contact structure that are stacked sequentially, wherein a cross-sectional area of the source contact structure is larger than a cross-sectional area of the source connection structure.

The details of one or more embodiments of the present disclosure are presented in the accompanying drawings and descriptions below. Other features, objectives, and advantages of the present disclosure will become apparent from the description, drawings, and claims.

### BRIEF DESCRIPTION OF THE DRAWINGS

To more clearly illustrate the technical solutions of the embodiments of the present disclosure, the following is a brief introduction to the drawings used in the description of the embodiments. It is obvious that the drawings described below are only some embodiments of the present disclosure. For those skilled in the art, other drawings may be obtained based on these drawings without creative labor.

FIG. 1 is a flowchart of a manufacturing method for a memory device according to some embodiments of the present disclosure.

FIG. 2a is a schematic structural view in a second direction of forming a first dielectric layer and a second dielectric layer on a substrate according to some embodiments of the present disclosure, and FIG. 2b is a schematic structural view in a first direction of forming the first dielectric layer and the second dielectric layer on the substrate according to some embodiments of the present disclosure.

FIG. 3a is a schematic structural view in the second direction of defining a second recess in the substrate according to some embodiments of the present disclosure, and FIG. 3b is a schematic structural view in the first direction of defining the second recess in the substrate according to some embodiments of the present disclosure.

FIG. 4a is a schematic structural view in the second direction of forming a shallow trench isolation (STI) structure according to some embodiments of the present disclosure, and FIG. 4b is a schematic structural view in the first direction of forming the shallow trench isolation (STI) structure according to some embodiments of the present disclosure.

FIG. 5a is a schematic structural view in the second direction of forming a second well region according to some embodiments of the present disclosure, and FIG. 5b is a schematic structural view in the first direction of forming the second well region according to some embodiments of the present disclosure.

FIG. 6a is a schematic structural view in the second direction of forming a hard mask layer according to some embodiments of the present disclosure, and FIG. 6b is a schematic structural view in the first direction of forming the hard mask layer according to some embodiments of the present disclosure.

FIG. 7a is a schematic structural view in the second direction of defining a first recess according to some embodiments of the present disclosure, and FIG. 7b is a schematic structural view in the first direction of defining the first recess according to some embodiments of the present disclosure.

FIG. 8a is a schematic structural view in the second direction of filling a first gate material according to some embodiments of the present disclosure, and FIG. 8b is a schematic structural view in the first direction of filling the first gate material according to some embodiments of the present disclosure.

FIG. 9a is a schematic structural view in the second direction of forming a contact window according to some embodiments of the present disclosure, and FIG. 9b is a schematic structural view in the first direction of forming the contact window according to some embodiments of the present disclosure.

FIG. 10a is a schematic structural view in the second direction of filling a second gate material according to some embodiments of the present disclosure, and FIG. 10b is a schematic structural view in the first direction of filling the second gate material according to some embodiments of the present disclosure.

FIG. 11a is a schematic structural view in the second direction of forming a semi-floating gate according to some embodiments of the present disclosure, and FIG. 11b is a schematic structural view in the first direction of forming the semi-floating gate according to some embodiments of the present disclosure.

FIG. 12a is a schematic structural view in the second direction of forming a first isolation portion according to some embodiments of the present disclosure, and FIG. 12b is a schematic structural view in the first direction of forming the first isolation portion according to some embodiments of the present disclosure.

FIG. 13a is a schematic structural view in the second direction of continuing to lower the shallow trench isolation structure to form the first isolation portion according to other embodiments of the present disclosure, and FIG. 13b is a schematic structural view in the first direction of continuing to lower the shallow trench isolation structure to form the first isolation portion according to other embodiments of the present disclosure.

FIG. 14a is a schematic structural view in the second direction of forming an inter-gate dielectric layer according to some embodiments of the present disclosure, and FIG. 14b is a schematic structural view in the first direction of forming the inter-gate dielectric layer according to some embodiments of the present disclosure.

FIG. 15a is a schematic structural view in the second direction of covering a third gate material (first gate layer) according to some embodiments of the present disclosure, and FIG. 15b is a schematic structural view in the first direction of covering the third gate material (first gate layer) according to some embodiments of the present disclosure.

FIG. 16a is a schematic structural view in the second direction of forming a control gate according to some embodiments of the present disclosure, and FIG. 16b is a schematic structural view in the first direction of forming the control gate according to some embodiments of the present disclosure.

FIG. 17a is a schematic structural view in the second direction of forming a second insulating layer according to some embodiments of the present disclosure, and FIG. 17b is a schematic structural view in the first direction of forming the second insulating layer according to some embodiments of the present disclosure.

FIG. 18a is a schematic structural view in the second direction of removing the hard mask layer according to some embodiments of the present disclosure, and FIG. 18b is a schematic structural view in the first direction of removing the hard mask layer according to some embodiments of the present disclosure.

FIG. 19a is a schematic structural view in the second direction of forming a spacer according to some embodiments of the present disclosure, and FIG. 19b is a schematic structural view in the first direction of forming the spacer according to some embodiments of the present disclosure.

FIG. 20 is a top view of forming a first interlayer dielectric layer on the memory device according to some embodiments of the present disclosure.

FIG. 21a is a schematic structural view in the first direction of forming the first interlayer dielectric layer according to some embodiments of the present disclosure, and FIG. 21b is a schematic structural view in a Y3 direction of forming the first interlayer dielectric layer according to some embodiments of the present disclosure.

FIG. 22 is a top view of forming a second interlayer dielectric layer on the memory device according to some embodiments of the present disclosure.

FIG. 23a is a schematic structural view in a Y1 direction of forming the second interlayer dielectric layer according to some embodiments of the present disclosure, FIG. 23b is a schematic structural view in a Y2 direction of forming the second interlayer dielectric layer according to some embodiments of the present disclosure, and FIG. 23c is a schematic structural view in the Y3 direction of forming the second interlayer dielectric layer according to some embodiments of the present disclosure.

FIG. 24 is a top view of forming a first metal layer on the memory device according to some embodiments of the present disclosure.

FIG. 25a is a schematic structural view in the Y1 direction of forming the first metal layer according to some embodiments of the present disclosure, FIG. 25b is a schematic structural view in the Y2 direction of forming the first metal layer according to some embodiments of the present disclosure, and FIG. 25c is a schematic structural view in the Y3 direction of forming the first metal layer according to some embodiments of the present disclosure.

FIG. 26 is a top view of forming a third interlayer dielectric layer and a second metal layer on the memory device according to some embodiments of the present disclosure.

FIG. 27a is a schematic structural view in the Y1 direction of forming the third interlayer dielectric layer and the second metal layer according to some embodiments of the present disclosure, FIG. 27b is a schematic structural view in the Y2 direction of forming the third interlayer dielectric layer and the second metal layer according to some embodiments of the present disclosure, and FIG. 27c is a schematic structural view in the Y3 direction of forming the third interlayer dielectric layer and the second metal layer according to some embodiments of the present disclosure.

### DETAILED DESCRIPTION

The following description will refer to the accompanying drawings of the embodiments of the present disclosure to provide a clear and complete description of the technical solutions of the embodiments of the present disclosure. It should be noted that the embodiments described herein are merely some examples of the embodiments of the present disclosure and not all of them. All other embodiments obtained by those skilled in the art based on the embodiments of the present disclosure without involving creative labor are within the scope of the present disclosure.

In the current manufacturing process of memory devices, when forming buried gate structures via semi-floating gates, subsequent back-end processes require high precision in metal routing. If alignment between vias and contacts is necessary, the process margin for the contact between vias and contacts becomes smaller. This reduction, due to overlay issues, decreases the contact area between vias and contacts, thereby increasing the corresponding contact resistance and affecting the performance of the semiconductor devices.

Therefore, a manufacturing method for a memory device is hereby provided. By enlarging the upper cross-sectional area of the source contact window structure corresponding to the source in the source lead-out region, the process margin for the contact between the via hole and the trench contact can be effectively increased. This reduces the corresponding contact resistance and enhances the performance of the semiconductor device.

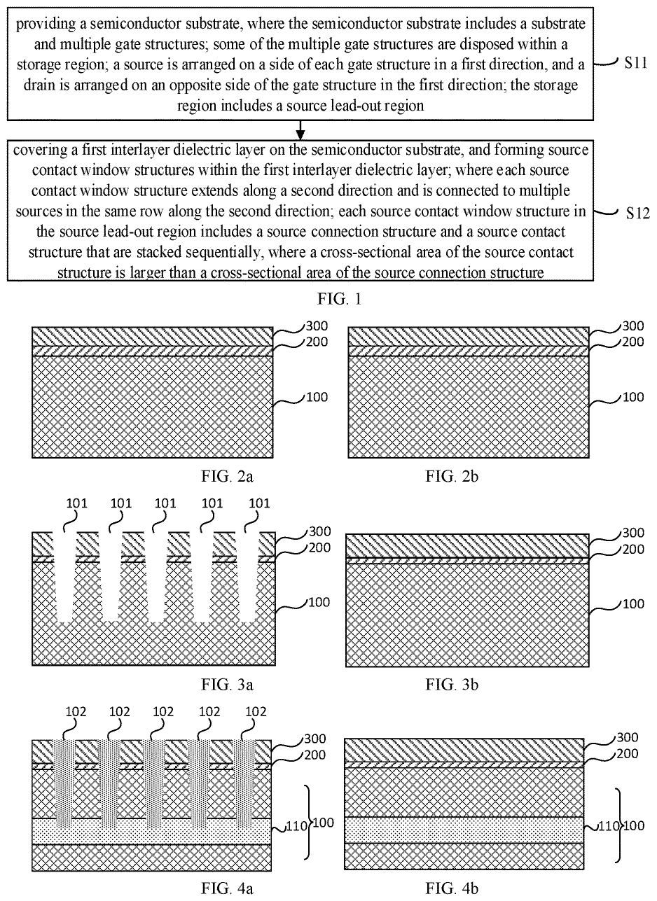

Referring to FIG. 1, FIG. 1 is a flowchart of a manufacturing method for a memory device according to some embodiments of the present disclosure.

The manufacturing method according to the present disclosure includes the following operations at blocks illustrated in FIG. 1.

At block S11: providing a semiconductor substrate, where the semiconductor substrate includes a substrate and multiple gate structures; some of the multiple gate structures are disposed within a memory region; a source is arranged on a side of each gate structure in a first direction, and a drain is arranged on an opposite side of the gate structure in the first direction; the memory region includes a source lead-out region.

The substrate may be any suitable substrate known in the art, such as at least one of the following materials: silicon (Si), germanium (Ge), silicon germanium (SiGe), silicon carbide (SiC), silicon germanium carbide (SiGeC), indium arsenide (InAs), gallium arsenide (GaAs), indium phosphide (InP), and other III/V compound semiconductors, as well as multi-layer structures composed of these semiconductors, or silicon on insulator (SOI), silicon stacked on insulator (SSOI), silicon stacked on germanium oxide (S-SiGeOI), germanium oxide on silicon (SiGeOI), and germanium oxide on germanium (GeOI).

In some embodiments, the operation S11 includes the following.

A semiconductor substrate is provided, including: providing a substrate and forming a hard mask layer on the substrate.

In some embodiments, the forming a hard mask layer on the substrate is as follows.

Referring to FIGS. 2a and 2b, FIGS. 2a-2b are schematic structural views in a second direction and a first direction, respectively, of forming a first dielectric layer and a second dielectric layer on a substrate according to some embodiments of the present disclosure.

The second direction corresponds to a wordline (WL) extension direction, also referred to as an X-direction, representing the row orientation. The first direction corresponds to a bitline (BL) extension direction, also referred to as a Y-direction, representing the column orientation. That is, the first and second directions are perpendicular to each other within the same horizontal plane.

As shown in FIG. 2a, in the second direction, a substrate 100 is provided, and a first dielectric layer 200 and a second dielectric layer 300 are sequentially formed on the substrate 100. As shown in FIG. 2b, in the first direction, the first dielectric layer 200 and the second dielectric layer 300 are sequentially formed on the substrate 100.

In some embodiments, the first dielectric layer 200 may be an oxide layer, such as a silicon oxide layer, and the second dielectric layer 300 may be a nitride layer, such as a silicon nitride layer.

In some embodiments, shallow trench isolation structures may be provided in the substrate, as described below.

Referring to FIGS. 3a and 3b, FIGS. 3a-3b are schematic structural views in the second direction and the first direction, respectively, of defining a second trench in the substrate according to some embodiments of the present disclosure.

As shown in FIG. 3a, in the second direction, second trenches 101 are defined in the substrate 100 from the second dielectric layer 300. As shown in FIG. 3b, in the first direction, the structure shown in FIG. 2b is maintained.

In some embodiments, multiple second trenches 101 are sequentially spaced apart along the second direction (X direction), and a bottom of each second trench 101 is higher than a bottom of the substrate 100, i.e., the second trench 101 extends into a portion of the substrate 100 (i.e., not penetrating the substrate 100).

Further, each second trench is filled with an insulating material to form a shallow trench isolation (STI) structure; and ion implantation is performed to form a first well region in the substrate.

Referring to FIGS. 4a and 4b, FIGS. 4a-4b are schematic structural views in the second direction and the first direction, respectively, of forming a shallow trench isolation (STI) structure according to some embodiments of the present disclosure.

As shown in FIG. 4a, in the second direction, the second trench 101 is filled with an insulating material to form the STI structure 102, and then the substrate 100 is subjected to ion implantation to form the first well region 110 in the substrate 100; where the STI structure 102 extends within the first well region 110, i.e., a bottom of the STI structure 102 is higher than a bottom of the first well region 110 and lower than a top of the first well region 110. As shown in FIG. 4b, in the first direction, the substrate 100 is subjected to ion implantation to form the first well region 110 in the substrate 100.

In some embodiments, a lowest point of the first well region 110 is higher than a lowest point of the substrate 100, and a highest point of the first well region 110 is lower than a highest point of the substrate 100, i.e., the first well region 110 is disposed within the substrate 100.

In some embodiments, the STI structure 102 is partially disposed within the substrate 100 and partially protrudes from the substrate 100 to define multiple active areas (AA) in the substrate. The STI structures 102 extend along the first direction and are spaced apart in the second direction.

After the STI structure 102 is formed, the second dielectric layer 300 is removed to expose a portion of the STI structure 102.

Ion implantation is performed on the substrate 100 again to form a second well region 120 on a side of the substrate 100 adjacent to the first dielectric layer 200; a doping type of the second well region 120 is different from a doping type of the first well region 110.

Referring to FIGS. 5a and 5b, FIGS. 5a-5b are schematic structural views in the second direction and the first direction, respectively, of forming a second well region according to some embodiments of the present disclosure.

As shown in FIG. 5a, in the second direction, the second dielectric layer 300 is removed to expose a portion of the STI structure 102, and the first dielectric layer 200 is used as a barrier layer to perform ion implantation on the substrate 100 to form the second well region 120 on a side of the substrate 100 adjacent to the first dielectric layer 200. As shown in FIG. 5b, in the first direction, the second dielectric layer 300 is removed to expose the first dielectric layer 200, and the first dielectric layer 200 is used as a barrier layer to perform ion implantation on the substrate 100, thereby forming the second well region 120 on a side of the substrate 100 adjacent to the first dielectric layer 200; where the second well region 120 is above the first well region 110.

In some embodiments, the first well region 110 and the second well region 120 have different doping types, i.e., the doping types of the first well region 110 and the second well region 120 are opposite. For example, when the first well region 110 is an N-type doped well region, the second well region 120 is a P-type doped well region; conversely, when the first well region 110 is a P-type doped well region, the second well region is an N-type doped well region.

A filling cover layer is formed on the first dielectric layer, with the first dielectric layer and the filling cover layer serving as the hard mask layer 400; where the filling cover layer fills a space between each adjacent two STI structures 102 and covers the STI structures 102; the filling cover layer may be a multi-layer structure or a single-layer structure.

When the filling cover layer is multi-layered, the filling cover layer may include a filling layer 410 and a protective layer 420. The filling layer 410 is formed on the first dielectric layer 200, where the filling layer 410 fills the space between adjacent STI structures 102; and the protective layer 420 is formed on the filling layer 410 and the STI structures 102. Alternatively, the filling cover layer is single-layered, such as a silicon nitride layer, which is filled between each adjacent STI structures 102 and formed on the STI structures 102, in which case the first dielectric layer 200 also serves as part of the hard mask layer 400.

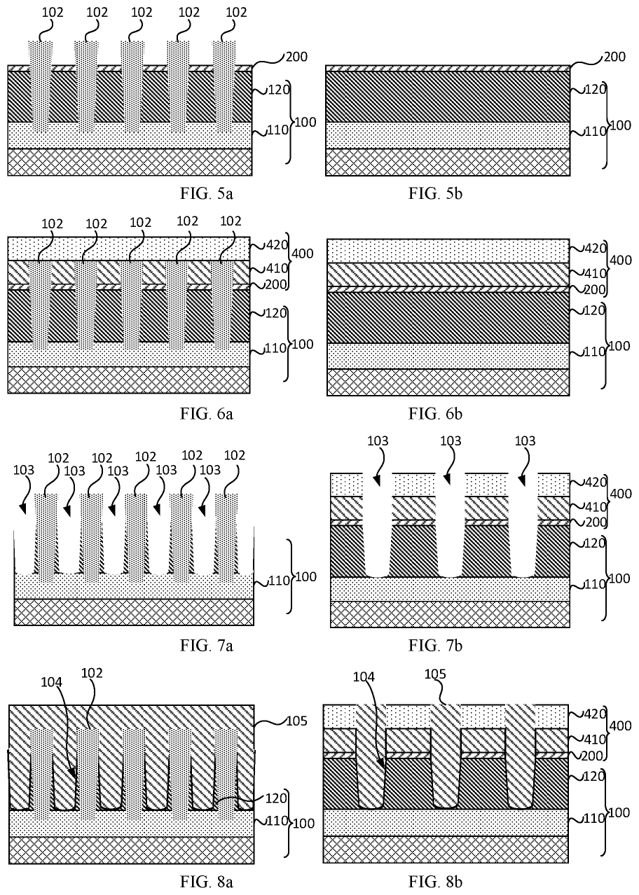

Referring to FIGS. 6a and 6b, FIGS. 6a-6b are schematic structural views in the second direction and the first direction, respectively, of forming a hard mask layer according to some embodiments of the present disclosure.

As shown in FIG. 6a, in the second direction, the filling layer 410 is formed on the first dielectric layer 200, the filling layer 410 fills the space between the adjacent two STI structures 102, and then the protective layer 420 is formed on the filling layer 410 and the STI structures 102. The filling layer 410 and the protective layer 420 constitute the filling cover layer, and the first dielectric layer 200, the filling layer 410, and the protective layer 420 form the hard mask layer 400. As shown in FIG. 6b, in the first direction, the filling layer 410 is formed on the first dielectric layer 200, and then the protective layer 420 is formed on the filling layer 410.

In some embodiments, the filling layer 410 may be a polycrystalline material filling layer, such as polysilicon, and the protective layer 420 may be an ON structure including a nitride layer and an oxide layer, such as an ON structure protective layer including a silicon nitride layer and a silicon oxide layer.

Then, multiple first trenches are defined in active areas of the substrate 100 from the hard mask layer 400; where some of the first trenches are located in the memory region, and others of the first trenches are located in the lead-out region; a portion of each first trench in the substrate is defined as a base trench.

Referring to FIGS. 7a and 7b, FIGS. 7a-7b are schematic structural views in the second direction and the first direction, respectively, of defining a first trench according to some embodiments of the present disclosure.

As shown in FIG. 7a, in the second direction, a portion of the hard mask layer 400 on the STI structure 102 between adjacent first trenches 103 is removed to expose a portion of the STI structure 102, and then first trenches 103 are defined in the active areas between the STI structures 102. As shown in FIG. 7b, in the first direction, multiple first trenches 103 are defined in the active areas of the substrate 100 from the hard mask layer 400. In the second direction, the first trenches 103 are separated by the STI structures 102, and in the first direction, the first trenches 103 are spaced apart.

In some embodiments, the first trench 103 sequentially penetrates the protective layer 420, the filling layer 410, the first dielectric layer 200, and the second well region 120, i.e., penetrating the hard mask layer 400 and the second well region 120, such that a bottom of the first trench 103 contacts the first well region 110, thereby exposing the first well region 110 through the first trench 103.

Subsequently, a gate structure is formed within the base trench.

The memory region may be divided into a drain lead-out region and a source lead-out region.

In some embodiments, the gate structure within the memory region includes a semi-floating gate and a control gate, while the gate structure within the lead-out region includes a semi-floating gate and a lead-out line. The semi-floating gate is formed at the bottom of the base trench, the control gate within the memory region fills the base trench and resides within the substrate, and at least a portion of the lead line within the lead-out region is located on substrate 100. Since a portion of the first trench resides within the memory region and another portion resides within the lead-out region, the gate structure containing the control gate is located in the memory region, while the gate structure containing the lead-out line is located in the lead-out region.

Thus, a gate insulating layer and a semi-floating gate are formed on a bottom of each base trench; where a portion of the semi-floating gate is in contact with the substrate, and another portion of the semi-floating gate is isolated from the substrate by the gate insulating layer.

Specifically, the manufacturing process for the semi-floating gate is as follows.

Referring to FIGS. 8a and 8b, FIGS. 8a-8b are schematic structural views in the second direction and the first direction, respectively, of filling a first gate material according to some embodiments of the present disclosure.

As shown in FIG. 8a, in the second direction, the first insulating layer 104 is formed on the inner wall of the base trench. The first insulating layer 104 may be formed on the exposed substrate using a thermal oxidation process, and the first gate material 105 is filled into the first trench 103, such that the first gate material 105 covers the first trenches 103. As shown in FIG. 8b, in the first direction, the first insulating layer 104 is formed on the inner wall of the base trench, and the first gate material 105 is filled into the first trench 103, such that the first gate material 105 is flush with the hard mask layer 400, i.e., flush with the protective layer 420.

In some embodiments, the first gate material 105 may be a polycrystalline material, such as polysilicon. After the first gate material 105 is filled, the first gate material 105 is chemically mechanically polished such that the first gate material 105 is flush with the protective layer 420.

In some embodiments, when forming the first insulating layer 104 on the inner wall of the first trench 103 and filling the first gate material 105 into the first trench 103, the first gate material 105 further covers the STI structure 102, as shown in FIG. 8a.

Then, a portion of the first gate material 105 within the first trench 103 and a corresponding portion of the first insulating layer 104 are removed to form a contact window; where at least a portion of the first insulating layer within the first trench segment is removed.

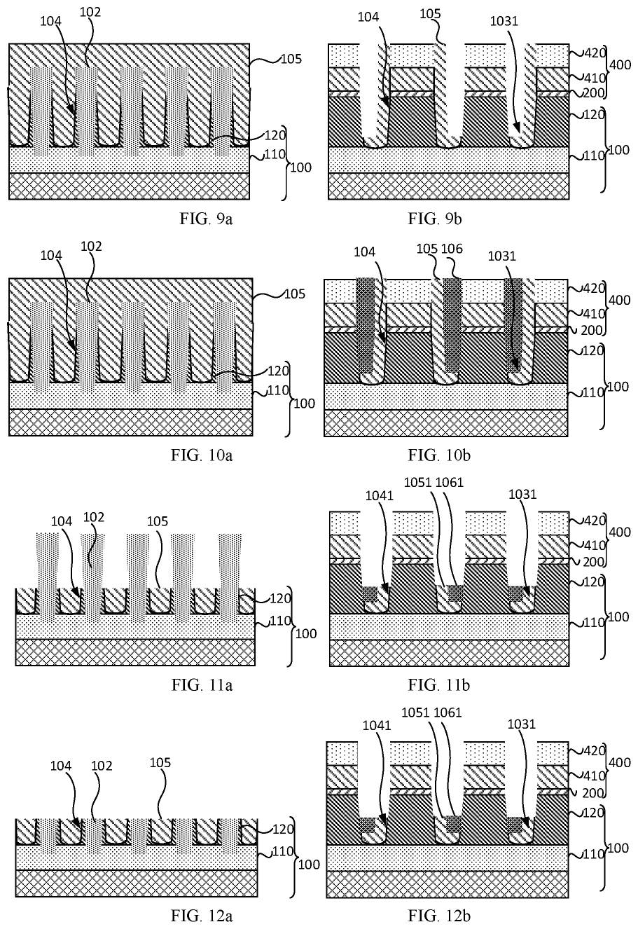

Referring to FIGS. 9a and 9b, FIGS. 9a-9b are schematic structural views in the second direction and the first direction, respectively, of forming a contact window according to some embodiments of the present disclosure.

As shown in FIG. 9b, in the first direction, a portion of the first gate material 105 and a corresponding portion of the first insulating layer 104 within the first trench 103 are removed, and a portion of the first gate material 105 and a portion of the first insulating layer 104 within a first trench segment 1031 of the base trench are removed, forming a contact window. As shown in FIG. 9a, in the second direction, the structure shown in FIG. 8a is maintained. The removal method may involve photolithography or etching.

The base trench includes the first trench segment 1031 and a second trench segment 1032, with the second trench segment 1032 located above the first trench segment 1031. That is, the first trench segment 1031 forms the bottom portion of the first trench 103, and the first trench segment 1031 is configured to accommodate the semi-floating gate, while the second trench segment 1032 is configured to accommodate the control gate or a portion of the lead-out line.

A second gate material 106 is filled into an unoccupied region of the first trench 103, i.e., forming the second gate material 106 above the contact window; where the second gate material 106 in the first trench segment 1031 contacts the substrate 100 through the contact window.

Referring to FIGS. 10a and 10b, FIGS. 10a-10b are schematic structural views in the second direction and the first direction, respectively, of filling a second gate material according to some embodiments of the present disclosure.

As shown in FIG. 10a, in the second direction, the structure shown in FIG. 9a is maintained. As shown in FIG. 10b, in the first direction, after removing a portion of the first gate material 105 and a corresponding portion of the first insulating layer 104 within the first trench 103, an unoccupied region of the first trench 103 is formed, and the second gate material 106 is filled into the unoccupied region of the first trench 103, that is, form the second gate material 106 above the contact window. Then, chemical mechanical polishing is performed to make the filled surface smooth. Since at least part of the first insulating layer 104 in the first trench segment 1031 is removed to form the contact window, the second gate material 106 in the first trench segment 1031 can contact the substrate 100 through the contact window, such as contacting the second well region 120. This means that one portion of the semi-floating gate contacts the substrate 100 through the contact window, while another portion remains isolated from the substrate 100 by the first insulating layer 104.

In some embodiments, the second gate material 106 may be formed using epitaxial growth or deposition processes. In some embodiments, the second gate material 106 is formed using an epitaxial growth process, ensuring that the region where the second gate material 106 contacts the substrate 100 is single-crystal material.

After the second gate material 106 is filled, a first gate 1051, a second gate 1061, and the gate insulating layer are formed, thereby forming the semi-floating gate.

Referring to FIGS. 11a and 11b, FIGS. 11a-11b are schematic structural views in the second direction and the first direction, respectively, of forming a semi-floating gate according to some embodiments of the present disclosure.

As shown in FIG. 11b, in the first direction, a portion of the first gate material 105, a portion of the second gate material 106, and a portion of the first insulating layer 104 in the first trench 103 are removed, while the first gate material 105, the second gate material 106, and the first insulating layer 104 in the first trench segment 1031 are retained. The first gate material 105 retained in the retained first trench segment 1031 serves as the first gate 1051, the second gate material 106 retained in the retained first trench segment 1031 serves as the second gate 1061, and the first insulating layer 104 retained in the retained first trench segment 1031 serves as the gate insulating layer 1041. The first gate 1051 and the second gate 1061 together form the semi-floating gate, where one portion of the semi-floating gate contacts the substrate 100 through the contact window, while another portion of the semi-floating gate is isolated from the substrate 100 by the gate insulating layer 1041. The bottom of the base trench retaining the first gate 1051, the second gate 1061, and the gate insulating layer 1041 constitutes the first trench segment 1031.

In some embodiments, when removing a portion of the first gate material 105, a portion of the second gate material 106, and a portion of the first insulating layer 104 within the first recess 103, a portion of the first gate material 105 covering the STI structure 102 is simultaneously removed, thereby continuing to expose the portion of the STI structure 102.

As shown in FIG. 11a, in the second direction, the first gate material 105 covering the STI structure 102 is simultaneously removed, exposing the STI structure 102.

In other embodiments, the manufacturing process for the semi-floating gate is as follows.

The first insulating layer 104 is formed on the inner wall of the base recess, and sacrificial material is formed on the first insulating layer 104, with the sacrificial material filling the first trench 103; a portion of the sacrificial material and a corresponding portion of the first insulating layer 104 are removed to form a contact window on the side wall of the first trench segment 1031 of the base trench. The remaining sacrificial material is removed and then a gate material is filled; a portion of the gate material and a corresponding portion of the first insulating layer 104 within the first trench 103 are removed to form the semi-floating gate and the gate insulating layer in the first trench segment 1031.

In this process, the remaining gate material in the first trench segment 1031 forms the semi-floating gate, and the remaining first insulating layer in the first trench segment 1031 forms the gate insulating layer. A portion of the semi-floating gate contacts the substrate through the contact window, while another portion of the semi-floating gate is isolated from the substrate by the gate insulating layer.

The sacrificial material may be a silicon-rich composite material or other suitable dielectric material.

Subsequently, the height of the STI structure is reduced to form a first isolation portion.

Referring to FIGS. 12a and 12b, FIGS. 12a-12b are schematic structural views in the second direction and the first direction, respectively, of forming a first isolation portion according to some embodiments of the present disclosure.

As shown in FIG. 12a, in the second direction, based on FIG. 11a, an exposed portion of the STI structure 102 is removed, i.e., the height of the STI structure 102 is reduced, such that the height of the STI structure 102 is no higher than the height of the semi-floating gate, thereby forming the first isolation portion. As shown in FIG. 12b, in the first direction, the structure shown in FIG. 11b may be maintained.

In some embodiments, when lowering the height of the STI structure 102 to form the first isolation portion, the remaining STI structure 102 may be flush with the semi-floating gate to serve as the first isolation portion.

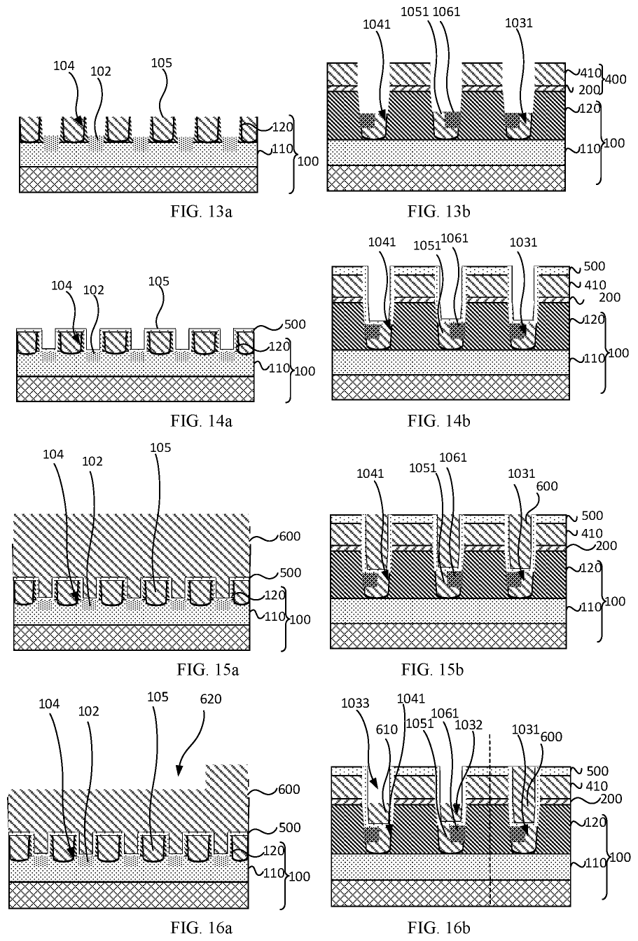

Referring to FIGS. 13a and 13b, FIGS. 13a-13b are schematic structural views in the second direction and the first direction, respectively, of continuing to lower the shallow trench isolation structure to form the first isolation portion according to other embodiments of the present disclosure.

As shown in FIG. 13a, in the second direction, based on FIG. 12a, a portion of the STI structure 102 is removed such that the height of the STI structure 102 is lower than the height of the semi-floating gate, and the remaining portion of the STI structure 102 serves as the first isolation portion. As shown in FIG. 13b, in the first direction, the protective layer 420 may be removed.

In some embodiments, the removal process may involve wet etching followed by dry etching.

Furthermore, the manufacturing process for the control gate in the memory region and the lead-out line in the lead-out region is as follows.

An inter-gate dielectric layer is formed, where the inter-gate dielectric layer at least covers the semi-floating gate.

Referring to FIGS. 14a and 14b, FIGS. 14a-14b are schematic structural views in the second direction and the first direction, respectively, of forming an inter-gate dielectric layer according to some embodiments of the present disclosure.

As shown in FIG. 14a, in the second direction, based on FIG. 13a, the inter-gate dielectric layer 500 is formed such that the inter-gate dielectric layer 500 covers the first isolation portion and the semi-floating gate in the first trench segment 1031, forming a tooth-like structure, thereby increasing the coupling area between the semi-floating gate and the control gate. As shown in FIG. 14b, in the first direction, the inter-gate dielectric layer 500 is formed such that the inter-gate dielectric layer 500 covers a portion of the first trench 103 above the semi-floating gate formed by the first gate 1051 and the second gate 1061, as well as the remaining hard mask layer 400 in a region between two adjacent first trenches 103.

Subsequently, a third gate material is covered on the inter-gate dielectric layer, specifically covering a first gate layer on the inter-gate dielectric layer 500. Excess third gate material is then removed until it is flush with the highest point of the first trench, i.e., the remaining portion of the third gate material is flush with the highest point of the first trench.

Referring to FIGS. 15a and 15b, FIGS. 15a-15b are schematic structural views in the second direction and the first direction, respectively, of covering a third gate material (first gate layer) according to some embodiments of the present disclosure.

As shown in FIG. 15a, in the second direction, based on FIG. 14a, a third gate material 600 (also the first gate layer) is covered on the inter-gate dielectric layer 500, and excess third gate material 600 is removed such that the third gate material 600 is flush with the highest point of the first trench 103. As shown in FIG. 15b, in the first direction, based on FIG. 14b, the third gate material 600 is deposited on the inter-gate dielectric layer 500, and excess third gate material 600 is removed such that the third gate material 600 is flush with the highest point of the first trench 103.

Subsequently, the control gate in the memory region and the lead-out line in the lead-out region are formed.

Referring to FIGS. 16a and 16b, FIGS. 16a-16b are schematic structural views in the second direction and the first direction, respectively, of forming a control gate according to some embodiments of the present disclosure.

As shown in FIG. 16b, in the first direction, based on FIG. 15b, a portion of the third gate material 600 in the first trench 103 in the memory region is removed to form a spare region 1033. The remaining third gate material 600 is not higher than the highest point of the base trench, and the remaining third gate material 600 serves as the control gate 610, i.e., the residual first gate layer within the base trench in the memory region serves as the control gate of the memory cell. As shown in FIG. 16a, in the second direction, a portion of the third gate material 600 on the first trench 103 in the memory region is removed to form an unoccupied region 620.

To more fully illustrate the structure of the device, the left side of the dashed line in FIG. 16b is a cross-sectional view showing the spare region 1033 formed in the first direction, corresponding to the cross-sectional view in the memory region in the Y1 direction in FIG. 20; the right side of the dashed line in FIG. 16b is a cross-sectional view of the third gate material 600 retained in the first trench 103 in the first direction, with the retained third gate material 600 serving as the lead-out line of the control gate of the memory cell, located in the lead-out region, corresponding to the cross-sectional view in the lead-out region in the Y2 direction in FIG. 20. As shown to the left of the dashed line in FIG. 16b, the third gate material 600 above the base trench in the memory region is removed to form the control gate 610. As shown in FIG. 16a, from the second direction, the unoccupied region 620 is formed.

Then, a second insulating layer 700 is formed on the spare region 1033 of the first trench 103 and the remaining first gate material on the first isolation portion.

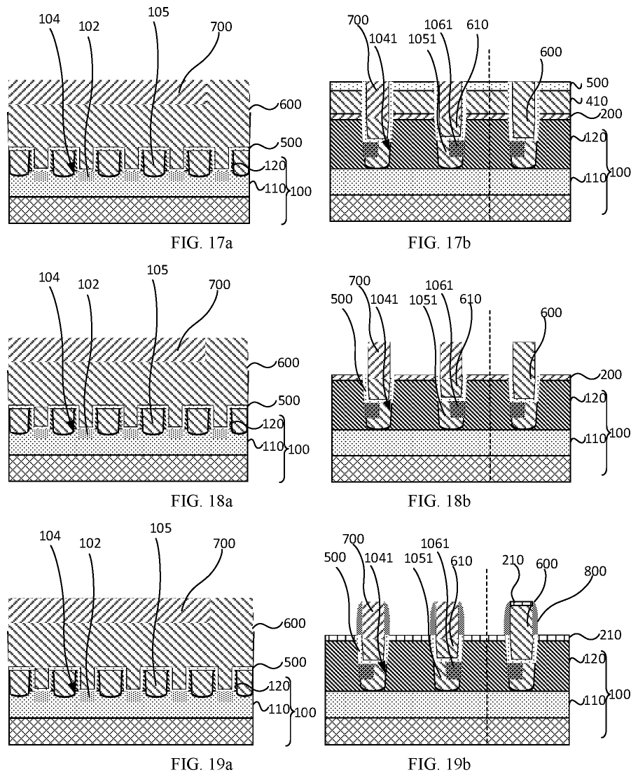

Referring to FIGS. 17a and 17b, FIGS. 17a-17b are schematic structural views in the second direction and the first direction, respectively, of forming a second insulating layer according to some embodiments of the present disclosure.

As shown in FIG. 17a, in the second direction, based on FIG. 16a, the second insulating layer 700 is formed in the unoccupied region 620 of the third gate material 600. As shown in FIG. 17b, in the first direction, based on FIG. 16b, the second insulating layer 700 is formed in the spare region 1033 of the first trench 103, and chemical mechanical polishing is performed to make the surface flat. The material of the second insulating layer 700 may be, for example, silicon oxide.

In some embodiments, in the first direction (e.g., the Y2 direction in FIG. 20), the third gate material 600 within the first trench 103 of a column in the lead-out region is fully retained; where the retained third gate material 600 in the first trench 103 of the column in the lead-out region serves as the connection point for the control gate of the memory cell, enabling the connection between the control gate 610 of the memory cell and the external environment. That is, the retained third gate material 600 in the first trench 103 in the lead-out region serves as the lead-out line for the control gates of the memory cells, with the lead-out line connecting the control gates 610 of multiple memory cells in the same row.

In some embodiments, in the second direction, at least one first trench in the lead-out region is shielded after every predetermined number of first trenches, retaining part of the third gate material 600 in the first trench 103 in the lead-out region; in the second direction, the third gate material 600 retained in the first trenches of the same row serves as the connection point for all control gates in the memory cells of that row, enabling the connection between the control gate 610 in the memory region of the same row and the external environment. A lead-out line of the control gate, i.e., lead-out line corresponding to the lead-out region, may be formed at a fixed distance BL, such as every 32 columns BL, such that the control gate 610 is connected to the outside through the lead-out line.

Additionally, the hard mask layer may be removed from the memory device, where a second isolation portion is a portion of the STI structure 102 exposed from the first isolation portion.

Referring to FIGS. 18a and 18b, FIGS. 18a-18b are schematic structural views in the second direction and the first direction, respectively, of removing the hard mask layer according to some embodiments of the present disclosure.

As shown in FIG. 18a, in the second direction, the first insulating layer 104 and the hard mask layer 400 on the second isolation portion of the STI structure in the second type of region in the first direction are removed. FIG. 18a shows the cross-sectional view of the second type of region in the second direction, i.e., the first isolation portion without the first insulating layer 104 and the hard mask layer 400. As shown in FIG. 18b, in the first direction, the first insulating layer 104 and the hard mask layer 400 on the region between adjacent base trenches and on the second isolation portion of the STI structure 102 in the first direction are removed.

In some embodiments, in the first direction, the first isolation portion and the second isolation portion are alternately spaced apart.

A spacer may be formed.

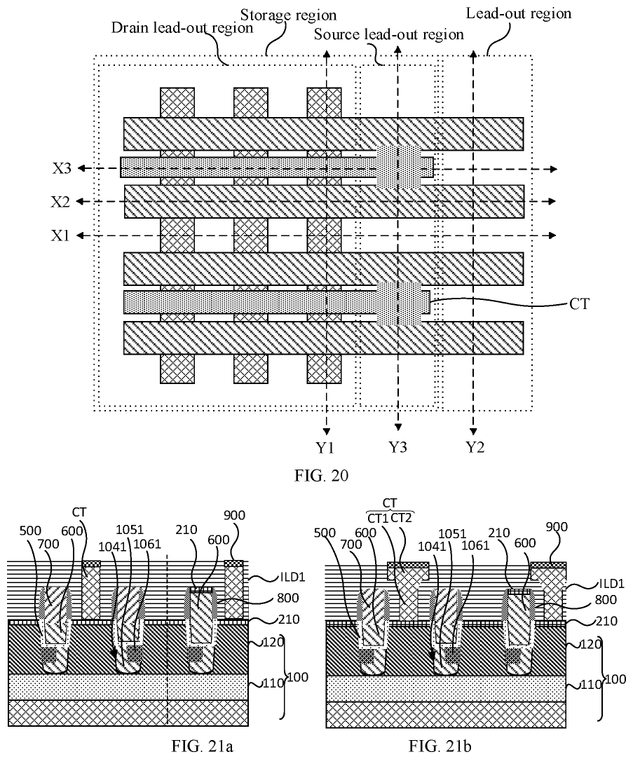

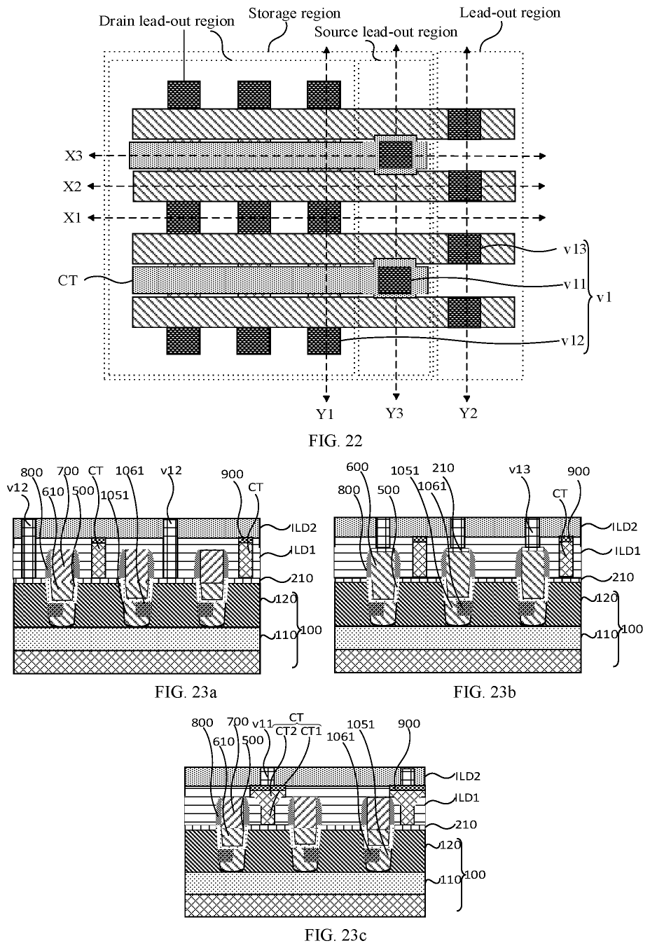

Referring to FIGS. 19a and 19b, FIGS. 19a-19b are schematic structural views in the second direction and the first direction, respectively, of forming a spacer according to some embodiments of the present disclosure.

As shown in FIG. 19a, in the second direction, the structure is as shown in FIG. 18a. As shown in FIG. 19b, in the first direction, the spacer 800 is formed on both sides of the second insulating layer 700 and/or both sides of the third gate material 600 remaining on each base trench, i.e., a spacer 800 is formed on both sides of the second insulating layer 700 remaining on the base trench in the memory region, as shown on the left side of the dashed line in FIG. 19b. On the base trench in the lead-out region, a spacer 800 is formed on both sides of the third gate material 600, i.e., on both sides of the lead-out line in the base trench in the lead-out region, as shown on the right side of the dashed lines in FIG. 19b.

In some embodiments, in the first direction, ion implantation is performed in the substrate on both sides of the first trench 103 to form a source and a drain, respectively. Subsequently, the source and drain are respectively led out through the subsequently-formed source contact window structure and drain lead-out structure.

In some embodiments, the first dielectric layer 200 is removed, and a metal silicide layer 210 is formed on a source region corresponding to the source, a drain region corresponding to the drain, and the third gate material.

By the above process, the semiconductor substrate is formed.

At block S12: covering a first interlayer dielectric layer on the semiconductor substrate, and forming source contact window structures within the first interlayer dielectric layer; where each source contact window structure extends along a second direction and is connected to multiple sources in the same row along the second direction; each source contact window structure in the source lead-out region includes a source connection structure and a source contact structure that are stacked sequentially, where a cross-sectional area of the source contact structure is larger than a cross-sectional area of the source connection structure.

The first interlayer dielectric layer is covered on the semiconductor substrate.

Referring to FIGS. 20, 21a, and 21b, FIG. 20 is a top view of forming a first interlayer dielectric layer on the memory device according to some embodiments of the present disclosure, FIGS. 21a-21b are schematic structural views in the first direction and a Y3 direction, respectively, of forming the first interlayer dielectric layer according to some embodiments of the present disclosure.

As shown in FIG. 20, in the first direction, it may be divided into three types of regions. Y1 is a first type of region in the first direction, i.e., the drain lead-out region, and the left side of the dashed line in the aforementioned FIG. [x]b (x refers to 1-19) are cross-sectional views of the first type of region in the first direction. Y2 is a second type of region in the first direction, i.e., the lead-out region, and the right side of the dashed line in the aforementioned FIG. [x]b (x refers to 1-19) are cross-sectional views of the second type of region in the first direction. Y3 is a third type of region in the first direction, i.e., the source lead-out region. In the second direction, it may be divided into three types of regions. X1 is a first type of region in the second direction where the second isolation portion is located. X2 is a second type of region in the second direction where the first isolation portion is located, and the aforementioned FIG. [x]a (x refers to 1-19) are cross-sectional views of the second type of region in the second direction. X3 is a third type of region in the second direction, corresponding to the strip-shaped source contact window structure.

As shown in FIGS. 20 and 21a, in the first direction, a first interlayer dielectric layer (ILD1) is covered on the semiconductor substrate. The first interlayer dielectric layer ILD1 is etched and filled to form the source contact window structures (CT) within the first interlayer dielectric layer ILD1. Each source contact window structure extends along the second direction, forming a strip-shaped source contact window structure that is connected to multiple sources in the same row along the second direction. The left side of the dashed lines in FIG. 21a is a cross-section in the Y1 direction, and the right side of the dashed lines in FIG. 21a is a cross-section in the Y2 direction. As shown in FIG. 21b, the source contact window structure in the source lead-out region includes a lower source connection structure CT1 and an upper source contact structure CT2. The source connection structure CT1 is connected to the source, while the cross-sectional area of the source contact structure CT2 is larger than the cross-sectional area of the source connection structure CT1, such that the subsequently formed source lead-out structure can be connected to the source contact structure.

In some embodiments, a trench contact region may be formed in the first interlayer dielectric layer ILD1 via lithography and etching. Conductive material (e.g., tungsten (W)) is then deposited within the trench contact region and subjected to chemical mechanical polishing to form the source contact window structure, for connecting the sources of memory cells in the same row to form a common source.

In some embodiments, the first interlayer dielectric layer ILD1 is etched. Within the source lead-out region, the spacer 800 serves as an etch stop layer to form a trench contact region that is wider at the top and narrower at the bottom. Subsequently, the source contact window structure, which includes lower source connection structure CT1 and an upper source contact structure CT2, is formed within the source lead-out region. The source connection structure CT1 contacts the isolation 800, where the source connection structure CT1 and the source contact structure CT2 are integrally formed.

In some embodiments, the source connection structure CT1 and the isolation wall 800 may be adjacent, i.e., the source connection structure CT1 and the spacer 800 are non-contact, as shown in FIG. 21b. In this case, a trench of uniform width is first formed, followed by widening the upper portion of the trench. Subsequently, the source connection structure CT1 is formed in the lower portion of the trench within the source lead-out region, while the source contact structure CT2 is formed in the upper portion. That is, the source contact structure CT2 is formed on top of the source connection structure CT1. The cross-sectional area of the source contact structure CT2 is larger than that of the source connection structure CT1, thereby constituting the source contact window structure.

In some embodiments, a barrier layer 900 (e.g., silicon nitride (SiN)) is deposited on the source contact window structure, and the barrier layer 900 on the source contact structure CT2 is retained via photolithography and etching.

In other embodiments, a trench contact region may be formed in the first interlayer dielectric layer ILD1 via photolithography and etching. After depositing a conductive material (e.g., tungsten (W)) in the trench contact region, the conductive material is etched back to form the source contact window structure. The etch-back depth may range from 400 Å to 600 Å, e.g., 500 Å. The barrier layer 900 (e.g., silicon nitride (SIN)) is redeposited and chemically-mechanically polished to retain the barrier layer 900 on the source contact structure CT2.

Subsequently, a second interlayer dielectric layer is covered on the first interlayer dielectric layer.

Referring to FIGS. 22, 23a, 23b, and 23c, FIG. 22 is a top view of forming a second interlayer dielectric layer on the memory device according to some embodiments of the present disclosure, FIGS. 23a, 23b, and 23c are schematic structural views in a Y1 direction, a Y2 direction, and the Y3 direction, respectively, of forming the second interlayer dielectric layer according to some embodiments of the present disclosure.

The second interlayer dielectric layer ILD2 is covered on the first interlayer dielectric layer ILD1, and a first lead-out structure v1 is formed in the second interlayer dielectric layer ILD2 and/or the first interlayer dielectric layer ILD1. The first lead-out structure v1 includes a source lead-out structure v11, a drain lead-out structure v12, and a first control gate lead-out structure v13.

As shown in FIG. 22, the drain lead-out structure v12 is located on the drain in the drain lead-out region, the source lead-out structure v11 is located on the source contact structure CT2 of the source in the source lead-out region, and the first control gate lead-out structure v13 is located on the lead-out line in the lead-out region.

The source lead-out structure v11, the drain lead-out structure v12, and the first control gate lead-out structure v13 are formed simultaneously. By leveraging the etch rate of the barrier layer 900, which is lower than that of the first interlayer dielectric layer ILD1 and second interlayer dielectric layer ILD2, different depths of through holes can be formed by adjusting the etch process. This enables the simultaneous formation of through holes for the source lead-out structure v11, the drain lead-out structure v12, and the first control gate lead-out structure v13. The through holes for the source lead-out structure v11, the drain lead-out structure v12, and the first control gate lead-out structure v13 respectively expose the source contact window structure in the source lead-out region, the drain in the drain lead-out region, and the lead line in the lead-out region. Conductive material is then filled into these vias to form the source lead-out structure v11, the drain lead-out structure v12, and the first control gate lead-out structure v13.

As shown in FIG. 23a, in the Y1 direction, within the drain lead-out region, the drain lead-out structure v12 is formed in the first interlayer dielectric layer ILD1 and the second interlayer dielectric layer ILD2 on the substrate on a side of the first trench. The source contact window structure CT is formed in the first interlayer dielectric layer ILD1 on the substrate on an opposite side of the first trench. That is, the drain lead-out structure v12 on the drain extends from the second interlayer dielectric layer ILD2 into the first interlayer dielectric layer ILD1 and is connected to a corresponding drain. Each source contact window structure CT extends along the second direction and is connected to multiple sources in the same row along the second direction. The source contact window structure CT is a strip-shaped structure. The drain lead-out structure v12 exists in the second interlayer dielectric layer ILD2, with each drain lead-out structure v12 corresponding to and connected to a drain, thereby leading out the drain via the drain lead-out structure v12.

As shown in FIG. 23b, in the Y2 direction, within the lead-out region, the first control gate lead-out structure v13 is formed in the second interlayer dielectric layer ILD2 and extends into the first interlayer dielectric layer ILD1. Each first control gate lead-out structure v13 is connected to a lead-out line shared by multiple control gates of the memory cells in the same row, i.e., the first control gate lead-out structure v13 is connected to the third gate material 600 (first gate layer) of the first trench, thereby leading out the control gate's corresponding lead-out line via the first control gate lead-out structure v13.

As shown in FIG. 23c, in the Y3 direction, within the source lead-out region, the source contact window structure CT is formed in the first interlayer dielectric layer ILD1 above the source. The source contact window structure CT extends along the second direction, forming a strip-shaped source contact window structure that connects multiple sources in the same row along the second direction. The source contact window structure CT within the source lead-out region includes the lower source connection structure CT1 and the upper source contact structure CT2, where the cross-sectional area of the source contact structure CT2 is larger than that of the source connection structure CT1. The source lead-out structure v11 is formed in the second interlayer dielectric layer ILD2 in the source lead-out region. Each source lead-out structure v11 corresponds to and is connected to a corresponding source contact window structure CT, i.e., the source lead-out structure v11 penetrates the barrier layer to connect with the source contact structure CT2. One source contact window structure CT corresponds to the source contact structure CT2 in one source lead-out region, thereby leading out the source via the source lead-out structure v11. The cross-sectional area of the source lead-out structure v11 may be smaller than that of the source contact structure CT2.

In some embodiments, the source lead-out structure v11 may be formed at fixed intervals BL, such as every 32 columns BL, enabling the source to connect to the external environment via the source lead-out structure v11.

Subsequently, a patterned first metal layer m1 is formed on the second interlayer dielectric layer, where the first metal layer includes a source line m11, a bit line m12, and a control gate contact m13.

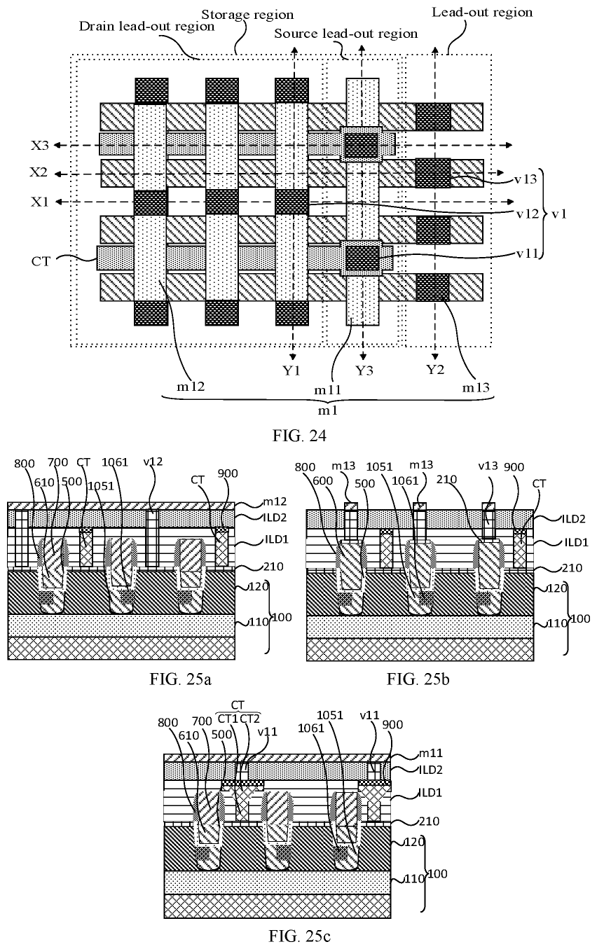

Referring to FIGS. 24, 25a, 25b, and 25c, FIG. 24 is a top view of forming a first metal layer on the memory device according to some embodiments of the present disclosure, FIGS. 25a, 25b, and 25c are schematic structural views in the Y1 direction, the Y2 direction, and the Y3 direction, respectively, of forming the first metal layer according to some embodiments of the present disclosure.

As shown in FIGS. 24 and 25a, within the drain lead-out region, the first metal layer m1—i.e., the bit line m12—is formed on the second interlayer dielectric layer ILD2. The bit line m12 extends along the first direction, with multiple bit lines m12 spaced apart in the second direction, each corresponding to a different column of drains. The bit line m12 is connected to multiple drain lead-out structures v12 within the same column along the first direction.

As shown in FIGS. 24 and 25b, within the lead-out region, the first metal layer m1—i.e., the control gate contact m13—is formed on the second interlayer dielectric layer ILD2. That is, the control gate contact m13 is formed on the first control gate lead-out structure v13. This enables the control gate contact m13 to be connected to the lead-out line of the control gate via the first control gate lead-out structure v13, i.e., to the third gate material 600 (first gate layer) within the lead-out region. The cross-sectional area of the control gate contact m13 may be larger than that of the first control gate lead-out structure v13, enabling the first control gate lead-out structure v13 to effectively connect upper and lower related structures.

As shown in FIGS. 24 and 25c, within the source lead-out region, a first metal layer m1—i.e., the source line m11—is formed on the source lead-out structure v11 of the second interlayer dielectric layer ILD2, where the source line m11 extends along the first direction. The source line m11 is connected to the source contact window structure CT via the source lead-out structure v11, thereby connecting to the source, and the source line m11 is connected to multiple source lead-out structures v11 of the same column.

Subsequently, a third interlayer dielectric layer ILD3 is covered on the first metal layer m1, and a second lead-out structure v2 is formed within the third interlayer dielectric layer, where the second lead-out structure v2 includes a second control gate lead-out structure v21; a patterned second metal layer m2 is then formed on the third interlayer dielectric layer ILD3, where the second metal layer m2 includes a word line m21, each word line m21 extending along the second direction and connected to at least one control gate contact m13 in the same row along the second direction.

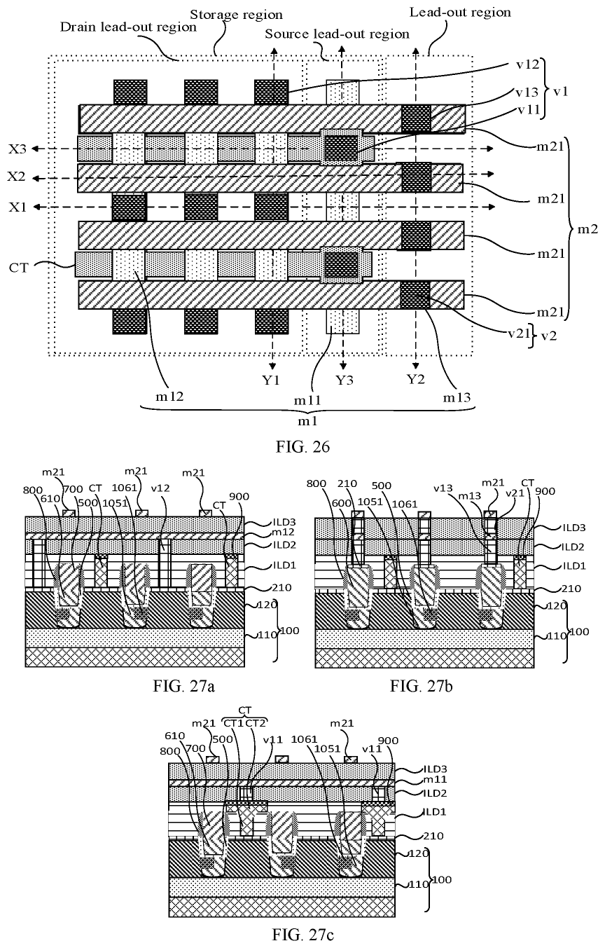

Referring to FIGS. 26, 27a, 27b, and 27c, FIG. 26 is a top view of forming a third interlayer dielectric layer and a second metal layer on the memory device according to some embodiments of the present disclosure, FIGS. 27a, 27b, and 27c are schematic structural views in the Y1 direction, the Y2 direction, and the Y3 direction, respectively, of forming the third interlayer dielectric layer and the second metal layer according to some embodiments of the present disclosure.

As shown in FIGS. 26 and 27a, within the drain lead-out region, the third interlayer dielectric layer ILD3 is formed on the first metal layer m1, and the patterned second metal layer m2, i.e., the word line m21, is formed on the third interlayer dielectric layer ILD3. The word line m21 is positioned on the gate structure and extends along the second direction.

As shown in FIGS. 26 and 27b, within the lead-out region, the third interlayer dielectric layer ILD3 is formed on the first metal layer m1, and the patterned second metal layer m2, i.e., the word line m21, is formed on the third interlayer dielectric layer ILD3. The second lead-out structure v2 further exists in the third interlayer dielectric layer ILD3. The second control gate lead-out structure v21 of the second lead-out structure v2 connects the first metal layer m1 to the second metal layer m2, i.e., the control gate contact m13 is connected to the word line m21 via the second control gate lead-out structure v21.

In some embodiments, the word line m21 extends along the second direction and may be connected to at least one second control gate lead-out structure v21 in the same row.

As shown in FIGS. 26 and 27c, in the Y3 direction, within the source lead-out region, the third interlayer dielectric layer ILD3 is formed on the first metal layer m1, and the patterned second metal layer m2, i.e., the word line m21, is formed on the third interlayer dielectric layer ILD3. The word line m21 is positioned on the gate structure and extends along the second direction.

In the embodiments, the upper cross-sectional area of the source contact window structure corresponding to the source in the source lead-out region is enlarged, which effectively increases the process margin for the contact between vias and trench contacts. This eliminates the need for via-to-contact hole connection processes, enhances the corresponding process margin, reduces contact resistance, and improves semiconductor device performance.

The present disclosure further includes a memory device including a substrate, multiple gate structures, a first interlayer dielectric layer, and multiple source contact window structures; where some of the multiple gate structures are disposed within a memory region; a source is arranged on a side of each gate structure in a first direction, and a drain is arranged on an opposite side of the gate structure in the first direction; the memory region includes a source lead-out region; the first interlayer dielectric layer covers the substrate, the gate structures, the drain, and the source; the multiple source contact window structures are located within the first interlayer dielectric layer, with each source contact window structure extending along a second direction and connected to multiple sources in the same row along the second direction; each source contact window structures in the source lead-out region includes a source connection structure and a source contact structure that are stacked sequentially, where a cross-sectional area of the source contact structure is larger than a cross-sectional area of the source connection structure.

Others of the multiple gate structures are located in a lead-out region; the multiple gate structures in the memory region are located within the substrate, and at least a portion of each gate structure in the lead-out region is located on the substrate.

In some embodiments, the gate structure includes a semi-floating gate, and the semi-floating gate is located on a bottom of a base trench of the substrate; a portion of the semi-floating gate is in contact with the substrate, and another portion of the semi-floating gate is isolated from the substrate by a gate insulating layer. The gate structure in the memory region further includes a control gate located on the semi-floating gate and isolated from the semi-floating gate by an inter-gate dielectric layer; the gate structure in the lead-out region further includes a lead-out line; at least a portion of the lead-out line is located on the substrate and serves as a lead-out line for the control gate of a memory cell, connecting the control gates of multiple memory cells in the same row.

In some embodiments, in the second direction, at least one corresponding lead-out line is provided for every predetermined number of control gates. The lead-out line serves as a connection point to connect multiple control gates in the same row to the external environment.

In some embodiments, the memory device further includes: a second interlayer dielectric layer, multiple source lead-out structures, and a first metal layer; where the second interlayer dielectric layer covers the first interlayer dielectric layer; the multiple source lead-out structures are located within the second interlayer dielectric layer in the source lead-out region, with each source lead-out structure corresponding to and connected to a corresponding source contact window structure; the first metal layer is located on the second interlayer dielectric layer, and a source line within the first metal layer is connected to multiple source lead-out structures of the same column within the source lead-out region.

In some embodiments, a barrier layer is further arranged, located on the source contact structure, where the source lead-out structure penetrates the barrier layer to be connected to the source contact window structure.

In some embodiments, the memory region further includes a drain lead-out region; the memory device further includes: multiple drain lead-out structures and multiple bit lines; where the multiple drain lead-out structures are located in the second interlayer dielectric layer and the first interlayer dielectric layer in the drain lead-out region of the memory region, with each drain lead-out structure connected to a corresponding drain; the first metal layer further includes the multiple bit lines located in the drain lead-out region, each bit line extending along the first direction and connected to corresponding drain lead-out structures in a same column along the first direction.

In some embodiments, the memory device further includes: multiple first control gate lead-out structures and multiple control gate contacts; where the multiple first control gate lead-out structures are located in the second interlayer dielectric layer and the first interlayer dielectric layer in the lead-out region, and each first control gate lead-out structure is connected in the lead-out region to a lead-out line shared by multiple control gates of the memory cells in the same row; the first metal layer further includes the multiple control gate contacts located in the lead-out region, with each control gate contact connected to a corresponding first control gate lead-out structure.

In some embodiments, the memory device further includes: a third interlayer dielectric layer, multiple second control gate lead-out structures, and a second metal layer; where the third interlayer dielectric layer is covered on the first metal layer; the multiple second control gate lead-out structures are located within the third interlayer dielectric layer in the lead-out region, with each second control gate lead-out structure corresponding to and connected to a corresponding control gate contact; the second metal layer is located on the third interlayer dielectric layer, and word lines within the second metal layer extend along the second direction, with each word line connected to the control gate contacts in the same row along the second direction via the second control gate lead-out structures.

In the embodiments, the source contact window structure corresponding to the source in the source lead-out region is configured to include an upper source contact structure and a lower source connection structure. The cross-sectional area of the source contact structure is larger than that of the source connection structure, which may effectively increase the process margin for the contact between vias and trench contacts. This eliminates the need for via-to-contact hole connection processes, enhances the corresponding process margin, reduces contact resistance, and improves semiconductor device performance.

The above description is merely some embodiments of the present disclosure and does not limit the scope of the present disclosure. Any equivalent structures or equivalent process variations made based on the content of the present disclosure and its drawings, or any direct or indirect application in other related technical fields, are all included within the scope of the present disclosure.

1. A manufacturing method for a memory device, comprising:
providing a semiconductor substrate; wherein the semiconductor substrate comprises a substrate and a plurality of gate structures; some of the plurality of gate structures are disposed within a memory region; a source is arranged on a side of each gate structure in a first direction, and a drain is arranged on an opposite side of the gate structure in the first direction; the memory region comprises a source lead-out region; and
forming a first interlayer dielectric layer on the semiconductor substrate, and forming a plurality of source contact window structures within the first interlayer dielectric layer; wherein each source contact window structure extends along a second direction and is connected to a plurality of the sources in a same row along the second direction; each source contact window structure in the source lead-out region comprises a source connection structure and a source contact structure that are stacked sequentially, wherein a cross-sectional area of the source contact structure is larger than a cross-sectional area of the source connection structure.

2. The manufacturing method according to claim 1, wherein others of the plurality of gate structures are located in a lead-out region; each gate structure in the memory region is located within the substrate, and at least a portion of each gate structure in the lead-out region is located on the substrate.

3. The manufacturing method according to claim 2, wherein the providing a semiconductor substrate comprises:
providing a substrate, and forming a hard mask layer on the substrate;
defining a plurality of first trenches in active areas of the substrate from the hard mask layer;
wherein some of the plurality of first trenches are located in the memory region, and others of the plurality of first trenches are located in the lead-out region; a portion of each first trench in the substrate is defined as a base trench;
forming a gate insulating layer and a semi-floating gate on a bottom of each base trench; wherein a portion of the semi-floating gate is in contact with the substrate, and another portion of the semi-floating gate is isolated from the substrate by the gate insulating layer; and
forming an inter-gate dielectric layer and a first gate layer in each first trench; removing a portion of the first gate layer in each first trench in the memory region to form a control gate of a corresponding memory cell, and retaining the first gate layer in each first trench in the lead-out region as a lead-out line for the control gate of a corresponding memory cell; wherein the lead-out line is connected to the control gates of memory cells in a same row as the lead-out line; a corresponding gate structure in the memory region comprises the semi-floating gate and the control gate within the memory region, and a corresponding gate structure in the lead-out region comprises the semi-floating gate and the lead-out line within the lead-out region.

4. The manufacturing method according to claim 3, wherein in the second direction, among the first trenches in the lead-out region, at least one first trench is shielded after every predetermined number of first trenches, and a portion of the first gate layer in each of the at least one first trench in the lead-out region is retained;
in the second direction, the first gate layer retained in each of the first trenches of a same row serves as a connection for all the control gates in the memory cells of the same row, enabling a connection between the first gate layers of the same row in the memory region and an external circuit.

5. The manufacturing method according to claim 1, wherein the forming a first interlayer dielectric layer on the semiconductor substrate, and forming a plurality of source contact window structures within the first interlayer dielectric layer comprise:
etching the first interlayer dielectric layer to form a trench contact region, that is strip-shaped, on the source; wherein a portion of the trench contact region in the source lead-out region is wider at a top and narrower at a bottom; and
filling the trench contact regions with conductive material to form the plurality of source contact window structures; wherein a lower portion of the trench contact region within the source lead-out region forms the source connection structure, and an upper portion of the trench contact region within the source lead-out region forms the source contact structure.

6. The manufacturing method according to claim 5, wherein a spacer is formed on both sides of each gate structure in the memory region;
the etching the first interlayer dielectric layer to form a trench contact region comprises:
etching the first interlayer dielectric layer; wherein the spacer corresponding to the source lead-out region serves as an etch stop layer to form the trench contact region, with the portion in the source lead-out region that is wider at the top and narrower at the bottom.

7. The manufacturing method according to claim 1, further comprising:
forming a second interlayer dielectric layer on the first interlayer dielectric layer, and forming a first lead-out structure in the second interlayer dielectric layer and/or the first interlayer dielectric layer; wherein the first lead-out structure comprises a plurality of source lead-out structures located within the source lead-out region, each source lead-out structure matched with a corresponding source contact window structure and connected within the source lead-out region to the corresponding source contact window structure;
forming a first metal layer, that is patterned, on the second interlayer dielectric layer; wherein the first metal layer comprises a source line located within the source lead-out region, and the source line extends along the first direction and is connected to corresponding source lead-out structures of a same column.

8. The manufacturing method according to claim 1, further comprising:
forming a barrier layer on the source contact structure, covering the first interlayer dielectric layer with a second interlayer dielectric layer, and forming a first lead-out structure in the second interlayer dielectric layer and/or the first interlayer dielectric layer;
wherein the first lead-out structure comprises a source lead-out structure, a drain lead-out structure, and a first control gate lead-out structure;
wherein the source lead-out structure, the drain lead-out structure, and the first control gate lead-out structure are formed simultaneously.

9. The manufacturing method according to claim 7, wherein the memory region further comprises a drain lead-out region;
the first lead-out structure further comprises a plurality of drain lead-out structures located in the drain lead-out region, each drain lead-out structure corresponding to and connected to a corresponding drain;
the first metal layer further comprises a plurality of bit lines located in the drain lead-out region, each bit line extending along the first direction and connected to corresponding drain lead-out structures in a same column along the first direction.

10. The manufacturing method according to claim 7, wherein others of the plurality of gate structures are located in a lead-out region;
the first lead-out structure further comprises a plurality of first control gate lead-out structures located within the lead-out region, each first control gate lead-out structure connected to a corresponding lead-out line shared by a plurality of memory cells in a same row;
the first metal layer further comprises a plurality of control gate contacts located in the lead-out region, each control gate contact connected to a corresponding first control gate lead-out structure.

11. The manufacturing method according to claim 10, further comprising:
covering a third interlayer dielectric layer on the first metal layer, and forming a second lead-out structure within the third interlayer dielectric layer; where the second lead-out structure comprises a plurality of second control gate lead-out structures located within the lead-out region, each second control gate lead-out structure connected to a corresponding control gate contact; and
forming a second metal layer, that is patterned, on the third interlayer dielectric layer; where the second metal layer comprises a plurality of word lines, each word line extending along the second direction and connected to corresponding control gate contacts in a same row along the second direction.

12. A memory device, comprising:
a substrate;
a plurality of gate structures; wherein some of the plurality of gate structures are disposed within a memory region; a source is arranged on a side of each gate structure in a first direction, and a drain is arranged on an opposite side of the gate structure in the first direction; the memory region comprises a source lead-out region;
a first interlayer dielectric layer, covering the substrate, the plurality of gate structures, the drain, and the source; and
a plurality of source contact window structures, located within the first interlayer dielectric layer; wherein each source contact window structure extends along a second direction and is connected to a plurality of the sources in a same row along the second direction; each source contact window structure in the source lead-out region comprises a source connection structure and a source contact structure that are stacked sequentially, wherein a cross-sectional area of the source contact structure is larger than a cross-sectional area of the source connection structure.

13. The memory device according to claim 12, wherein others of the plurality of gate structures are located in a lead-out region; each gate structure in the memory region is located within the substrate, and at least a portion of each gate structure in the lead-out region is located on the substrate.

14. The memory device according to claim 13, wherein each gate structure comprises:
a semi-floating gate, located on a bottom of each base trench of the substrate; wherein a portion of the semi-floating gate is in contact with the substrate, and another portion of the semi-floating gate is isolated from the substrate by a gate insulating layer;
wherein each gate structure in the memory region further comprises a control gate located on the semi-floating gate and isolated from the semi-floating gate by an inter-gate dielectric layer;
wherein each gate structure in the lead-out region further comprises a lead-out line; at least a portion of the lead-out line is located on the substrate and serves as a lead-out line for the control gate of a memory cell, for connecting the control gates of multiple the memory cells in a same row.

15. The memory device according to claim 14, wherein in the second direction, at least one corresponding lead-out line is provided for every predetermined number of the control gates; the lead-out line serves as a connection to connect the control gates in the same row to an external circuit.

16. The memory device according to claim 12, wherein the memory device further comprises:
a second interlayer dielectric layer, covering the first interlayer dielectric layer;
a plurality of source lead-out structures, located within the second interlayer dielectric layer, with each source lead-out structure corresponding to and connected to a corresponding source contact window structure; and
a first metal layer, located on the second interlayer dielectric layer; wherein a source line within the first metal layer is connected within the source lead-out region to corresponding source lead-out structures of a same column.

17. The memory device according to claim 16, wherein the memory device further comprises:
a barrier layer, located on the source contact structure; wherein each source lead-out structure penetrates the barrier layer to be connected to a corresponding source contact window structure.

18. The memory device according to claim 16, wherein the memory region further comprises a drain lead-out region; the memory device further comprises:
a plurality of drain lead-out structures, located in the second interlayer dielectric layer and the first interlayer dielectric layer in the drain lead-out region of the memory region, with each drain lead-out structure connected to a corresponding drain;
wherein the first metal layer further comprises a plurality of bit lines located in the drain lead-out region, each bit line extending along the first direction and connected to corresponding drain lead-out structures in a same column along the first direction.

19. The memory device according to claim 16, wherein the memory device further comprises:
a plurality of first control gate lead-out structures, located in the second interlayer dielectric layer and the first interlayer dielectric layer in the lead-out region, with each first control gate lead-out structure connected in the lead-out region to a corresponding lead-out line shared by control gates of memory cells in a same row;
the first metal layer further comprises a plurality of control gate contacts located in the lead-out region, with each control gate contact connected to a corresponding first control gate lead-out structure.

20. The memory device according to claim 19, wherein the memory device further comprises:
a third interlayer dielectric layer, covering the first metal layer;
a plurality of second control gate lead-out structures, located within the third interlayer dielectric layer in the lead-out region, with each second control gate lead-out structure corresponding to and connected to a corresponding control gate contact; and
a second metal layer, located on the third interlayer dielectric layer; wherein each word line within the second metal layer extends along the second direction and is connected to corresponding control gate contacts in a same row along the second direction.
